(19) United States
(12) Patent Application Publication
(10) Pub. No.: US 2015/0109868 A1
(43) Pub. Date: Apr. 23, 2015

(54) NONVOLATILE SEMICONDUCTOR MEMORY DEVICE

(71) Applicant: Kabushiki Kaisha Toshiba, Minato-ku (JP)

(72) Inventor: Takeshi SONEHARA, Yokkaichi-shi (JP)

(73) Assignee: Kabushiki Kaisha Toshiba, Minato-ku (JP)

(21) Appl. No.: 14/162,996

(22) Filed: Jan. 24, 2014

Related U.S. Application Data
(60) Provisional application No. 61/894,474, filed on Oct. 23, 2013.

(51) Int. Cl. G11C 7/24

(52) U.S. Cl. CPC G11C 7/24
USPC 365/189.16

(57) ABSTRACT

A nonvolatile semiconductor memory device according to the embodiment includes a memory cell array including memory cells; and a data write unit, the memory cells including a first selected memory cell defined for a memory cell targeted to data write, a second selected memory cell defined for a memory cell targeted to the data write next to the first selected memory cell, and non-selected memory cells defined for other memory cells, and the data write unit, at the time of write operation to the first selected memory cell, providing the second selected memory cell with a first non-selection electric pulse having electric energy within a range causing no change in the physical state of a memory element, and providing the non-selected memory cells with a second non-selection electric pulse having smaller electric energy than the first non-selection electric pulse.

### CROSS-REFERENCE TO RELATED APPLICATIONS

This application is based upon and claims the benefit of priority from the prior U.S. Provisional Application 61/894,474, filed on Oct. 23, 2013, the entire contents of which are incorporated herein by reference.

### BACKGROUND

1. Field

The embodiment of the present invention relates to a nonvolatile semiconductor memory device.

2. Description of the Related Art

In recent years, as for nonvolatile semiconductor memory devices, electrically rewritable variable resistance elements such as ReRAMs, PRAMs and PCRAMs have received attention as successor memories to flash memories.

For example, a ReRAM memory cell has a simple structure because it includes a variable resistance element and a selection element, that is, a rectifier element both formed at an intersection of a bit line and a word line.

In this case, if a semiconductor such as Si is used in a rectifier element of the memory cell, when a current flow in a forward direction or a reverse direction through the rectifier element for a long time, it may accumulate electrons or holes in the rectifier element. Then, property of the rectifier element may deteriorate.

### BRIEF DESCRIPTION OF THE DRAWINGS

FIG. 1 provides an example of a block diagram of a nonvolatile semiconductor memory device according to the embodiment.

FIG. 2 is a perspective view showing an example of a structure of a memory cell in the nonvolatile semiconductor memory device according to the embodiment.

FIG. 3 is a perspective view showing an example of a structure of a memory cell in the nonvolatile semiconductor memory device according to the embodiment.

FIG. 4 is a diagram illustrative of an example of combinations of arrangements of a variable resistance element and a rectifier element of the memory cell in the nonvolatile semiconductor memory device according to the embodiment.

FIG. 5 is a diagram illustrative of an example of the states of currents flowing in a selected memory cell and a non-selected memory cell in the nonvolatile semiconductor memory device according to the embodiment.

FIG. 6 is a diagram illustrative of an example of a bias state at the time of unipolar operation in the nonvolatile semiconductor memory device according to the embodiment.

FIG. 7 is a diagram illustrative of an example of a bias state at the time of bipolar operation in the nonvolatile semiconductor memory device according to the embodiment.

FIG. 8 provides an example of a reference diagram illustrative of the effect of impact ionization phenomena.

FIG. 9 is a diagram showing an example of a bias state of a memory cell array at the time of write operation in the nonvolatile semiconductor memory device according to the embodiment.

FIG. 10 is a diagram showing an example of electric pulses supplied to a memory cell at the time of write operation in the nonvolatile semiconductor memory device according to the embodiment.

FIG. 11 is a diagram showing an example of a bias state of a memory cell array at the time of write operation in the nonvolatile semiconductor memory device according to the embodiment.

FIG. 12 is a diagram showing an example of electric pulses supplied to a memory cell at the time of write operation in the nonvolatile semiconductor memory device according to the embodiment.

FIG. 13 is a diagram showing an example of a bias state of a memory cell array at the time of write operation in the nonvolatile semiconductor memory device according to the embodiment.

FIG. 14 is a diagram showing an example of electric pulses supplied to a memory cell at the time of write operation in the nonvolatile semiconductor memory device according to the embodiment.

FIG. 15 is a diagram showing an example of a bias state of a memory cell array at the time of write operation in the nonvolatile semiconductor memory device according to the embodiment.

FIG. 16 is a diagram showing an example of a bias state of a memory cell array at the time of write operation in the nonvolatile semiconductor memory device according to the embodiment.

FIG. 17 is a diagram showing an example of a bias state of a memory cell array at the time of write operation in the nonvolatile semiconductor memory device according to the embodiment.

FIG. 18 is a diagram illustrative of an example of the selecting order of memory cells at the time of write operation in the nonvolatile semiconductor memory device according to the embodiment.

FIG. 19 is a diagram illustrative of an example of address assignments to memory cells in the nonvolatile semiconductor memory device according to the embodiment.

FIG. 20 is a diagram illustrative of the selecting order of memory cells at the time of write operation in the nonvolatile semiconductor memory device according to the embodiment.

FIG. 21 is a diagram illustrative of an example of the selecting order of memory cells at the time of write operation in the nonvolatile semiconductor memory device according to the embodiment.

FIG. 22 is a diagram illustrative of an example of address assignments to memory cells in the nonvolatile semiconductor memory device according to the embodiment.

FIG. 23 is a diagram showing an example of electric pulses supplied to a memory cell at the time of write operation in the nonvolatile semiconductor memory device according to the embodiment.

FIG. 24 is a diagram showing an example of electric pulses supplied to a memory cell at the time of write operation in the nonvolatile semiconductor memory device according to the embodiment.

FIG. 25 is a diagram showing an example of electric pulses supplied to a memory cell at the time of write operation in the nonvolatile semiconductor memory device according to the embodiment.

FIG. 26 is a diagram showing an example of electric pulses supplied to a memory cell at the time of write operation in the nonvolatile semiconductor memory device according to the embodiment.

FIG. 27 is a diagram showing an example of electric pulses supplied to a memory cell at the time of write operation in the nonvolatile semiconductor memory device according to the embodiment.

FIG. 28 is a diagram showing an example of electric pulses supplied to a memory cell at the time of write operation in the nonvolatile semiconductor memory device according to the embodiment.

### DETAILED DESCRIPTION

A nonvolatile semiconductor memory device according to the embodiment comprises a memory cell array including first lines, second lines intersecting the first lines, and memory cells arranged at the intersections of the first lines and the second lines; and a data write unit operative to execute write operation to the memory cells, the memory cell including a memory element operative to change the physical state in accordance with electric energy, and a selection element serially connected thereto and operative to switch between selection/non-selection of the memory cell, the memory cells including a first selected memory cell defined for a memory cell targeted to the data write, a second selected memory cell defined for a memory cell targeted to the data write next to the first selected memory cell, and non-selected memory cells defined for other memory cells, and the data write unit, at the time of write operation to the first selected memory cell, providing the second selected memory cell with a first non-selection electric pulse having electric energy within a range causing no change in the physical state of the memory element, and providing the non-selected memory cells with a second non-selection electric pulse having smaller electric energy than the first non-selection electric pulse.

A nonvolatile semiconductor memory device according to the embodiment is described below with reference to the drawings.

### [General System]

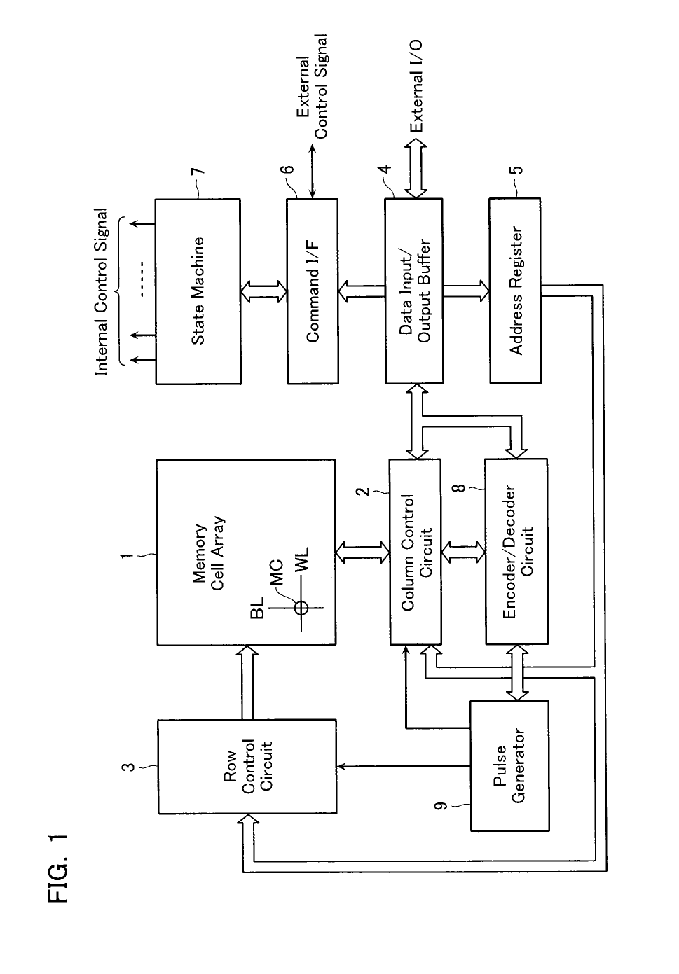

FIG. 1 is a block diagram of the nonvolatile semiconductor memory device according to the embodiment.

The nonvolatile semiconductor memory device has a memory cell array 1, which includes bit lines BL (first lines), word lines WL (second lines) intersecting the bit lines BL, and memory cells MC provided at the intersections of the bit lines BL and the word lines WL.

A column control circuit 2, provided at a position adjacent to the memory cell array 1 in the bit line BL direction, controls bit lines BL in the memory cell array to execute write operation and read operation to the memory cells MC.

A row control circuit 3, provided at a position adjacent to the memory cell array 1 in the word line WL direction, selects from among word lines WL in the memory cell array 1 to apply voltages for write operation and read operation to the memory cells MC.

A data input/output buffer 4 is connected to an external host, not shown, via an I/O line and operative to receive write data, provide read data, and receive address data and command data. The data input/output buffer 4 sends the received write data to the column control circuit 2, receives the data read out of the column control circuit 2 and provides it to external. An address supplied from external to the data input/output buffer 4 is sent to the column control circuit 2 and the row control circuit 3 via an address register 5. A command supplied from the host to the data input/output buffer 4 is sent to a command interface 6.

The command interface 6 receives an external control signal from the host and decides whether the data input to the data input/output buffer 4 is a command or an address. If it is a command, then it is transferred to a state machine 7 as a received command signal.

The state machine 7 is operative to manage the nonvolatile semiconductor memory device. It receives commands from the host to execute write operation, read operation, data input/output management and so forth.

The data input to the data input/output buffer 4 from the host is transferred to an encoder/decoder circuit 8, and an output signal therefrom is input to a pulse generator 9. In accordance with this input signal, the pulse generator 9 provides a write pulse of a certain voltage at certain timing. The pulse generated at the pulse generator 9 is transferred to any line selected by the column control circuit 2 and the row control circuit 3.

Further, the column control circuit 2, the row control circuit 3, the data input/output buffer 4, the address register 5, the command interface 6, the state machine 7, the encoder/decoder circuit 8, and the pulse generator 9 are contained in the data write unit.

### [Memory Cell]

The memory cell MC according to the embodiment is described next.

The memory cell MC includes a memory element and a selection element, for example, a rectifier element, which are serially connected at an intersection of a word line WL and a bit line BL.

The memory element may include a variable resistance element or a phase change element. The variable resistance element is an element formed of a material having a resistance value variable in accordance with a voltage, current, heat and so forth. The phase change element is an element formed of a material having a property of matter, such as a resistance value and a capacity, variable in accordance with a phase change.

In this connection, the phase change (phase transition) includes the below-listed modes.

(1) A metal-semiconductor transition, a metal-insulator transition, a metal-metal transition, an insulator-insulator transition, an insulator-semiconductor transition, an insulator-metal transition, a semiconductor-semiconductor transition, a semiconductor-metal transition, or a semiconductor-insulator transition.

(2) A phase change between quantum states, such as a metal-superconductor transition.

(3) A paramagnet-ferromagnetic transition, an antiferromagnet-ferromagnetic transition, a ferromagnetic-ferromagnetic transition, a ferrimagnet-ferromagnetic transition, or a transition composed of a combination of these transitions.

(4) A paraelectric-ferroelectric transition, a paraelectric-pyroelectric transition, a paraelectric-piezoelectric transition, a ferroelectric-ferroelectric transition, an antiferroelectric-ferroelectric transition, or a transition composed of a combination of these transitions.

(5) Transitions composed of combinations of the transitions in the above (1)-(4), for example, a transition from a metal, an insulator, a semiconductor, a ferroelectric, a paraelectric, a pyroelectric, a piezoelectric, a ferromagnetic, a ferrimagnet, a helimagnet, a paramagnet, or an antiferromagnet to a ferromagnetic ferroelectric, or the reverse transition.

According to this definition, the phase change element is contained in the variable resistance element. The variable resistance element in the present embodiment though means an element mainly composed of a metal oxide, a metal compound, an organic thin film, carbon, carbon nanotubes or the like.

Additionally, in the embodiment, a ReRAM using a variable resistance element as a memory element, and a PCRAM using a phase change element as a memory element, for example, are contained in the targets of the variable resistance memory.

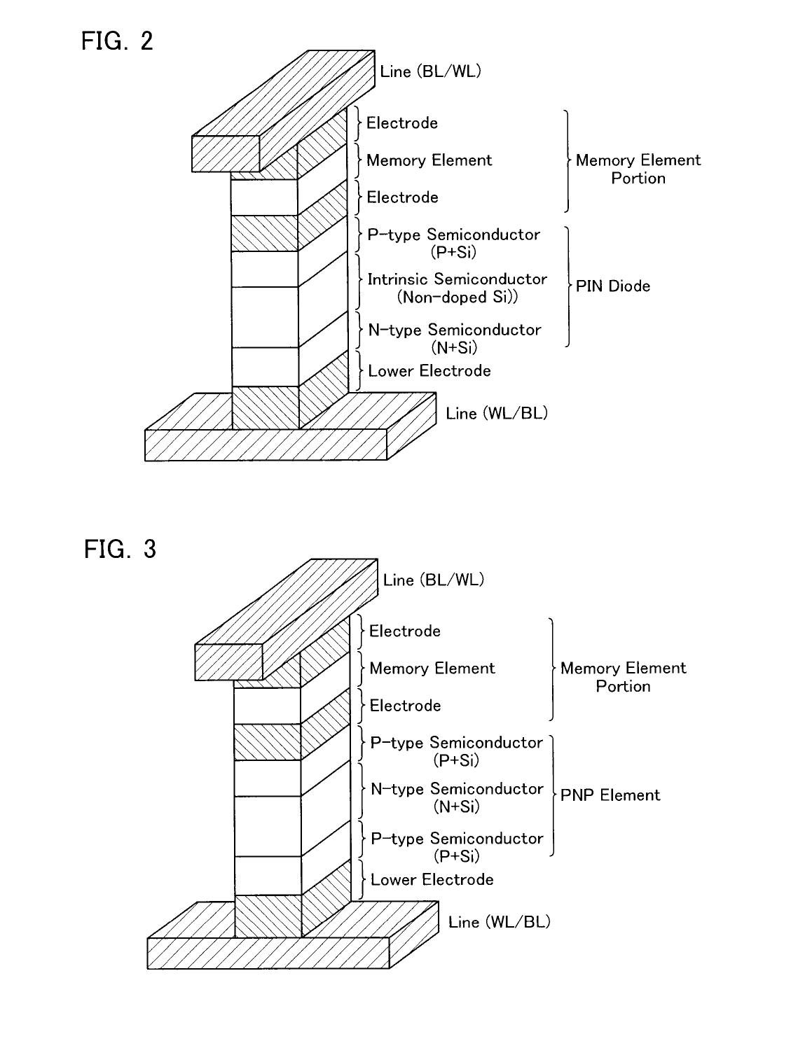

FIG. 2 is a perspective view showing a structure of a memory cell in the nonvolatile semiconductor memory device according to the embodiment. In the shown case, a PIN diode is used as a rectifier element of a memory cell MC.

As shown in FIG. 2, the memory cell MC is provided at an intersection of a word line WL (or bit line BL) in a lower layer and a bit line BL (or word line WL) in an upper layer. The memory cell MC includes a lower electrode, a PIN diode composed of an n-type semiconductor (N+Si)/an intrinsic semiconductor (non-doped Si)/a p-type semiconductor (P+Si), and a memory element portion composed of an electrode/a memory element/an electrode, which are stacked from the lower layer toward the upper layer and formed in a pillar shape. Further, the PIN diode has a film thickness set within a range of 50 n to 150 nm.

FIG. 3 is a perspective view showing a structure of a memory cell in the nonvolatile semiconductor memory device according to the embodiment. In the shown case, a PNP element is used as a rectifier element of a memory cell MC.

As shown in FIG. 3, the memory cell MC is provided at an intersection of a word line WL (or bit line BL) in a lower layer and a bit line BL (or word line WL) in an upper layer. From the lower layer toward the upper layer, a lower electrode, a PNP element composed of a p-type semiconductor (P+Si)/an n-type semiconductor (N+Si)/a p-type semiconductor (P+Si), and a memory element portion are stacked and formed. The PNP element also has a film thickness set within a range of 50 n to 150 nm. In addition, as the rectifier element of the memory cell MC, an NPN element composed of an n-type semiconductor (N+Si)/a p-type semiconductor (P+Si)/an n-type semiconductor (N+Si) may also be used instead of the PNP element.

As shown in FIGS. 2 and 3, these memory cells MC can be formed of the cross point type. Therefore, it is possible to form a three-dimensionally with large memory capacity. In addition, the variable resistance element has a DRAM-level fast operation.

The following description is mainly given on the precondition that the memory element is a variable resistance element such as a ReRAM.

If the memory cell array 1 is formed in a three-dimensional structure, combinations of the positional relation between the variable resistance element and the rectifier element of the memory cell MC and the direction of the rectifier element can be selected variously at every layer.

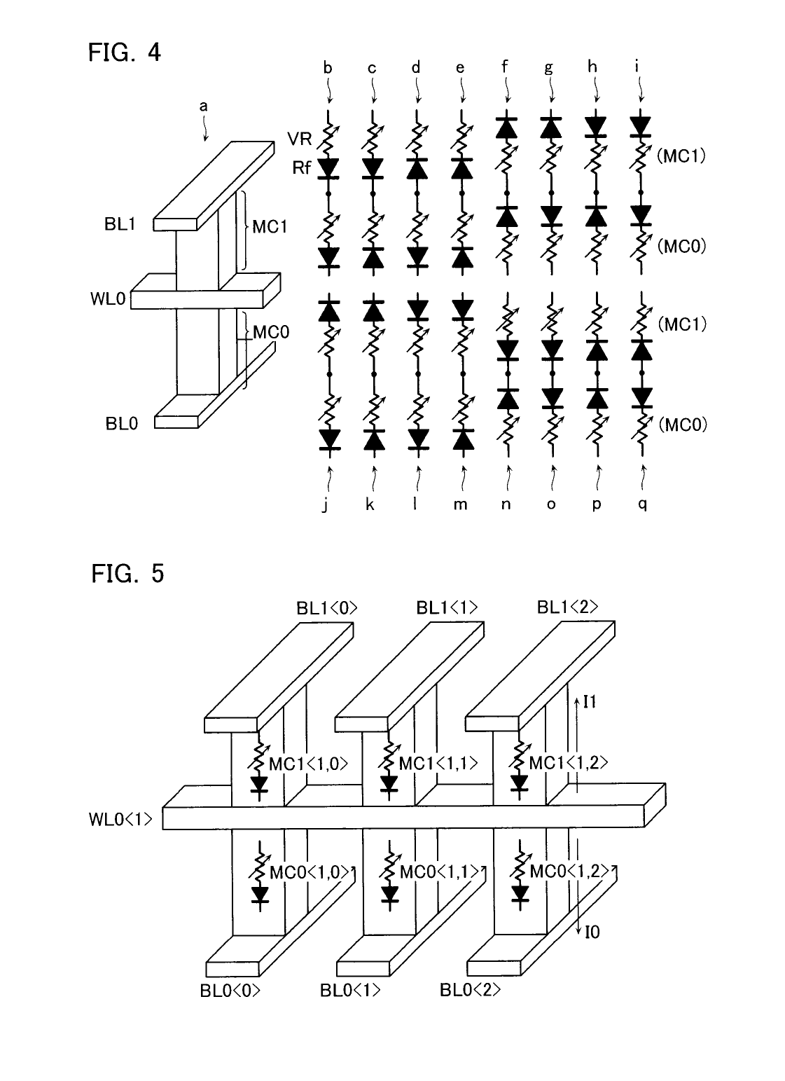

FIG. 4 is a diagram illustrative of combinations of arrangements of the variable resistance element and the rectifier element of the memory cell in the nonvolatile semiconductor memory device according to the embodiment.

FIG. 4 is a diagram illustrative of patterns of combinations of memory cells MC0, MC1 when the memory cell MC0 belonging to a memory cell layer in the lower layer of the memory cell array 1 and the memory cell MC1 belonging to a memory cell layer in the upper layer of the memory cell array 1 share a word line WL0 as shown in a of FIG. 4. In FIG. 4, the rectifier element is represented by a symbol of a diode for convenience though the rectifier element is not limited to the diode.

As shown in b-q of FIG. 4, 16 patterns can be considered as combinations of the memory cell MC0 and the memory cell MC1, such as a reversed positional relation between the variable resistance element VR and the rectifier element Rf, and a reversed direction of the rectifier element Rf. These patterns can be selected in consideration of the operating characteristic, the operating method, the production steps and so forth.

### [Write Operation]

Write operation of the memory cell MC is described next.

Write operation is operation of subjecting the variable resistance element VR of the memory cell MC to set operation or reset operation. A high resistance state of the variable resistance element VR is changed to a low resistance state by the set operation. A low resistance state is changed to a high resistance state by the reset operation. Further, the below-described current values, voltage values and so forth are presented by way of example and may differ in accordance with materials, sizes and so forth of the variable resistance element VR and the rectifier element Rf.

FIG. 5 is a diagram illustrative of the states of currents flowing in a selected memory cell and a non-selected memory cell in the nonvolatile semiconductor memory device according to the embodiment.

In the case of FIG. 5, a memory cell MC0 in the lower layer is provided at an intersection of a bit line BL0 and a word line WL0. A memory cell MC1 in the upper layer is provided at an intersection of the word line WL0 and a bit line BL1. The word line WL0 is shared between the memory cells MC0 and MC1.

In addition, the combination of arrangements of the memory cells MC0 and MC1 has a pattern shown in b of FIG. 4. In a word, the memory cell MC0 includes a rectifier element Rf and a variable resistance element VR stacked in order from the bit line BL0 toward the word line WL0. The rectifier element Rf is arranged in a forward direction from the word line WL0 toward the bit line BL0. On the other hand, the memory cell MC1 includes a rectifier element Rf and a variable resistance element VR stacked in order from the word line WL0 toward the bit line BL1. The rectifier element Rf is arranged in a forward direction from the bit line BL1 toward the word line WL0.

The following consideration is given to write operation when a memory cell MC0<1,1> provided at an intersection of a bit line BL0<1> in a memory cell layer in the lower layer and a word line WL0<1> is a selected memory cell.

Write operation to a memory cell MC can be achieved by two methods: unipolar operation capable of realizing set operation and reset operation in accordance with identical-polarity bias application; and bipolar operation capable of realizing set operation and reset operation in accordance with different-polarity bias application.

At the start, unipolar operation is described.

In set operation, a current having a current density of 1×10⁵ to 1×10⁷ A/cm² or a voltage of 1-2 V, for example, is applied to the variable resistance element VR. Therefore, in the case of set operation in the memory cell MC, for application of such the certain current or voltage, a flow of forward current is caused in the rectifier element Rf.

In reset operation, a current having a current density of 1×10³ to 1×10⁶ A/cm² or a voltage of 1-3 V, for example, is applied to the variable resistance element VR. Therefore, in the case of reset operation in the memory cell MC, for application of such the certain current or voltage, a flow of forward current is caused in the rectifier element Rf.

In the case of FIG. 5, the word line WL0<1> connected to the memory cell MC0<1,1> is provided with 3 V and the bit line BL0<1> with 0 V, thereby realizing reset operation of the memory cell MC0<1,1>.

As for memory cells MC, however, one word line WL or bit line BL is usually connected to memory cells MC as shown in FIG. 5. In this case, a certain current or voltage is applied to a selected memory cell MC. At the same time, it is required to prevent set/reset operation in other non-selected memory cells MC.

In the case of FIG. 5, if 0 V is also applied to bit lines BL0<0> and <2> similar to the bit line BL0<1>, a forward current I0 flows in non-selected memory cells MC0<1,0> and <1,2>, thereby causing the reset operation. In addition, if 0 V is applied to bit lines BL1<0>-<2>, non-selected memory cells MC1<1,0>-<1,2> are reverse-biased. Therefore, it is required to suppress an off current I1 from flowing.

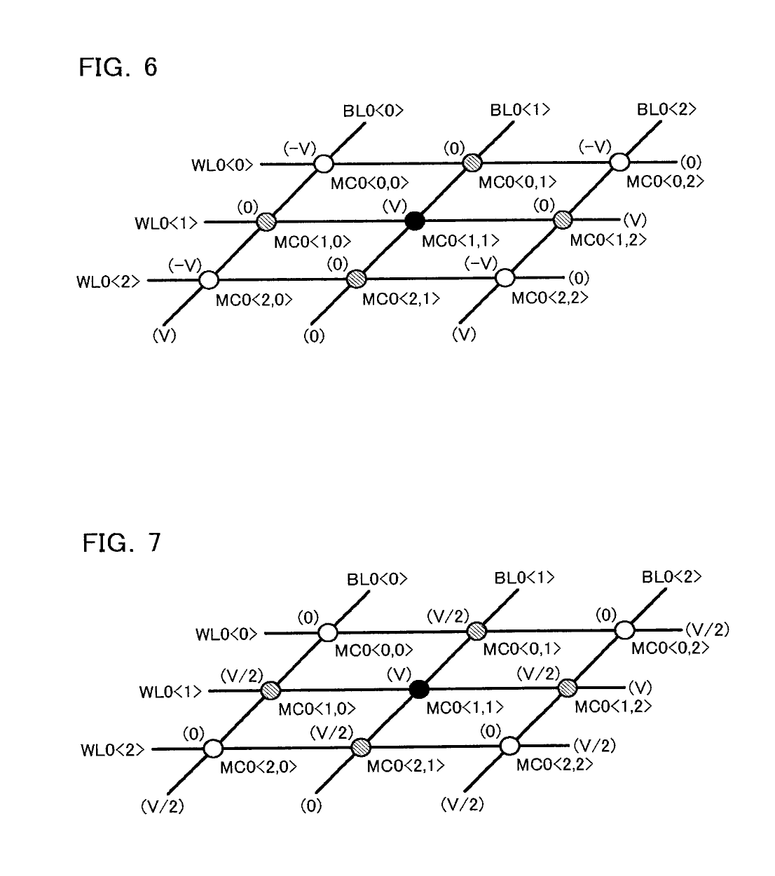

Then, in the case of unipolar operation, the memory cell array 1 may be, for example, brought into a bias state as shown in FIG. 6.

FIG. 6 is a diagram illustrative of an example of a bias state at the time of unipolar operation in the nonvolatile semiconductor memory device according to the embodiment. Hereinafter, a memory cell connected to a word line WL<i> (i is a positive integer) and a bit line BL<j> (j is a positive integer) is represented by MC<i,j>.

As shown in FIG. 6, a selected word line WL0<1> is provided with a certain voltage V (for example, 3 V) and other word lines WL0<0> and <2> with 0 V. In addition, a selected bit line BL0<1> is provided with 0 V and other bit lines BL0<0> and <2> with the voltage V. As a result, a selected memory cell MC0<1,1> is provided with a potential difference V. Non-selected memory cells MC0<0,0>, <0,2>, <2,0> and <2,2> connected between non-selected word lines WL0<0> and <2> and non-selected bit lines BL0<0> and <2> are provided with a potential difference −V. Other memory cells MC0, that is, non-selected memory cells MC0<0,1>, <1,0>, <1,2> and <2,1> (hereinafter referred to as “half-selected memory cells”) only connected to either of the selected word line WL0<1> and the selected bit line BL0<1> are provided with a potential difference 0 V.

In this case, it is sufficient to use such as a diode having a voltage-current characteristic that current almost does not flow until −V when reverse-biased and current flows sharply when forward-biased. It is possible to execute write set/reset operation only in the selected memory cell MC0<1,1> using such the element in the memory cell MC.

Subsequently, bipolar operation is described.

In the case of bipolar operation, basically, the following points should be considered: (1) flows of current are caused in two directions through the memory cell MC, different from the case of unipolar operation; (2) the operating speed, the operating current and the operating voltage vary from the values in unipolar operation; and (3) even half-selected memory cells MC are biased.

FIG. 7 is a diagram illustrative of an example of a bias state at the time of bipolar operation in the nonvolatile semiconductor memory device according to the embodiment. It is a diagram illustrative of the above (3).

In the case of FIG. 7, a selected word line WL0<1> is provided with a certain voltage V (for example, 3 V) and other word lines WL0<0> and <2> with a voltage V/2. In addition, a selected bit line BL0<1> is provided with 0 V and other bit lines BL0<0> and <2> with the voltage V/2.

In this case, half-selected memory cells MC0<0,1>, <1,0>, <1,2> and <2,1> are provided with the voltage V/2 as shown in FIG. 7. Therefore, in bipolar operation, it is sufficient to use a rectifier element that current almost does not flow when a voltage below V/2.

On the basis of the above, in the nonvolatile semiconductor memory device using memory cells MC including a variable resistance element and a rectifier element, it is preferable to use a rectifier element capable of causing a sufficient flow of on-current while sufficiently suppressing off-current.

Then, the embodiment facilitates the occurrence of impact ionization phenomena in a rectifier element, thereby increasing on-current at the time of write operation.

The following description is given to the effect exerted by the use of impact ionization phenomena.

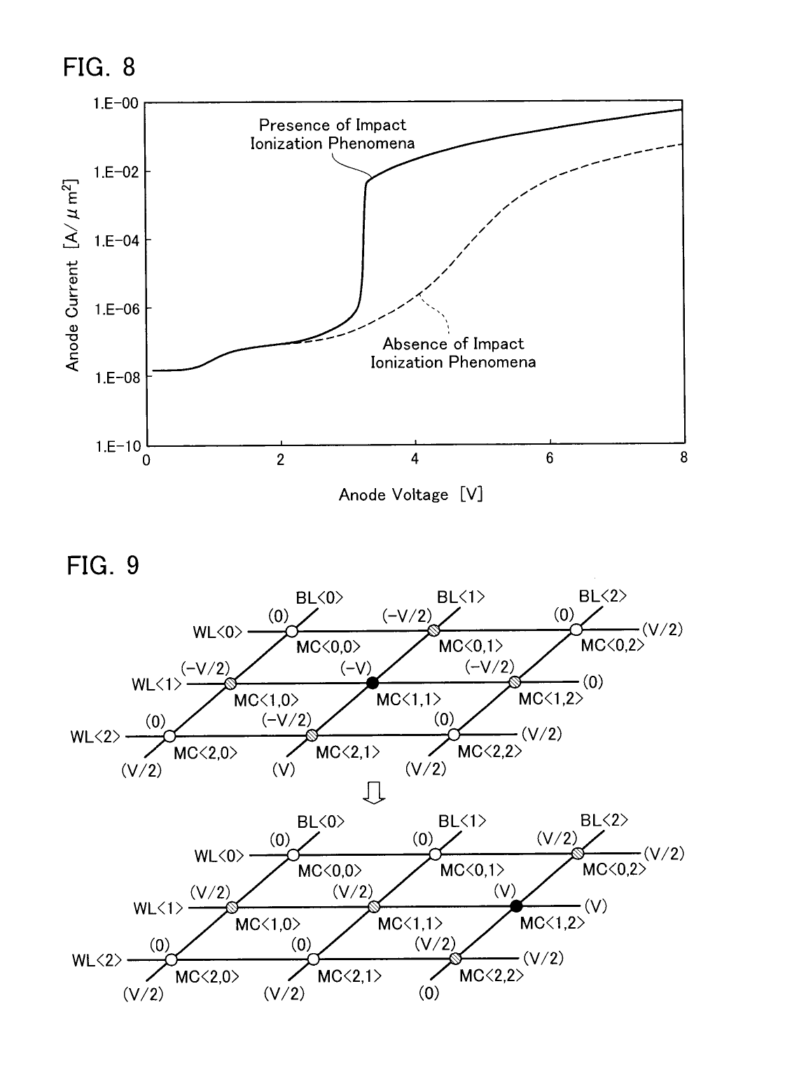

FIG. 8 provides an example of a reference diagram illustrative of the effect of impact ionization phenomena. It is a diagram relating to a punch-through element and showing the anode current while the anode potential is changed from 0 V to 8 V.

In the case of a punch-through element not using impact ionization phenomena, as the anode potential is changed from 0 V to 8 V, the anode current relatively gently rises from about 1×10⁻⁸ A/μm² to about 1×10⁻² A/μm² as can be found.

On the other hand, in the case of a punch-through element using impact ionization phenomena, as long as the anode potential falls within a range of 0 V to 3 V, the anode current only flows to the same extent as that in the case without the use of impact ionization phenomena. When the anode potential reaches around 3 V, though, the anode current sharply rises up to around 1×10⁻² A/μm². By the time the anode potential reaches 8 V, the anode current flows to an extent near 1×10° A/μm² as can be found.

In a word, in the case of the punch-through element, it possible to improve a ratio between on-current and off-current (hereinafter referred to as an “on/off ratio”) and increase on-current using impact ionization phenomena.

The following description is given to write operation using impact ionization phenomena. Hereinafter, the description is simplified by using a memory cell array 1 including a single-layered memory cell layer. This embodiment is though also applicable to a memory cell array 1 including memory cell layers. This point should be noted.

FIG. 9 is a diagram showing an example of a bias state of a memory cell array at the time of write operation in the nonvolatile semiconductor memory device according to the embodiment.

This example is an example using a variable resistance element that is subjected to set/reset operation when the absolute value of a potential difference is equal to V or higher. It utilizes a middle voltage having an absolute value lower than V in charging the rectifier element by electric charge.

At the start, the write operation is executed to a selected memory cell, that is, a memory cell MC<1,1>. In this case, as shown in the upper part of FIG. 9, the data write unit is used to provide a selected word line WL<1> with 0 V, non-selected word lines WL<0> and <2> with a voltage V/2, a selected bit line BL<1> with a voltage V, and non-selected bit lines BL<0> and <2> with the voltage V/2. As a result, only a selected memory cell MC<1,1> is provided with a voltage −V having a potential-difference absolute value of V or higher, thereby executing the set/reset operation to the selected memory cell MC<1,1>.

In addition, half-selected memory cells MC<0,1>, <1,0>, <1,2> and <2,1> are provided with a potential difference −V/2 (a first non-selection electric pulse or a first non-selection potential difference). Non-selected memory cells MC<0,0>, <0,2>, <2,0> and <2,2> are provided with a potential difference 0 V (a second non-selection electric pulse or a second non-selection potential difference).

Subsequently, the write operation is executed to a selected memory cell, that is, a memory cell MC<1,2> (a second selected memory cell), which locates on the same word line WL<1> as the former selected memory cell MC<1,1> (a first selected memory cell). In this case, as shown in the lower part of FIG. 9, the data write unit is used to provide a selected word line WL<1> with a voltage V, non-selected word lines WL<0> and <2> with a voltage V/2, a selected bit line BL<2> with 0 V, and non-selected bit lines BL<0> and <1> with the voltage V/2. As a result, only a selected memory cell MC<1,2> is provided with a voltage V (a selection electric pulse) having a potential-difference absolute value of V or higher, thereby executing the set/reset operation to the selected memory cell MC<1,2>.

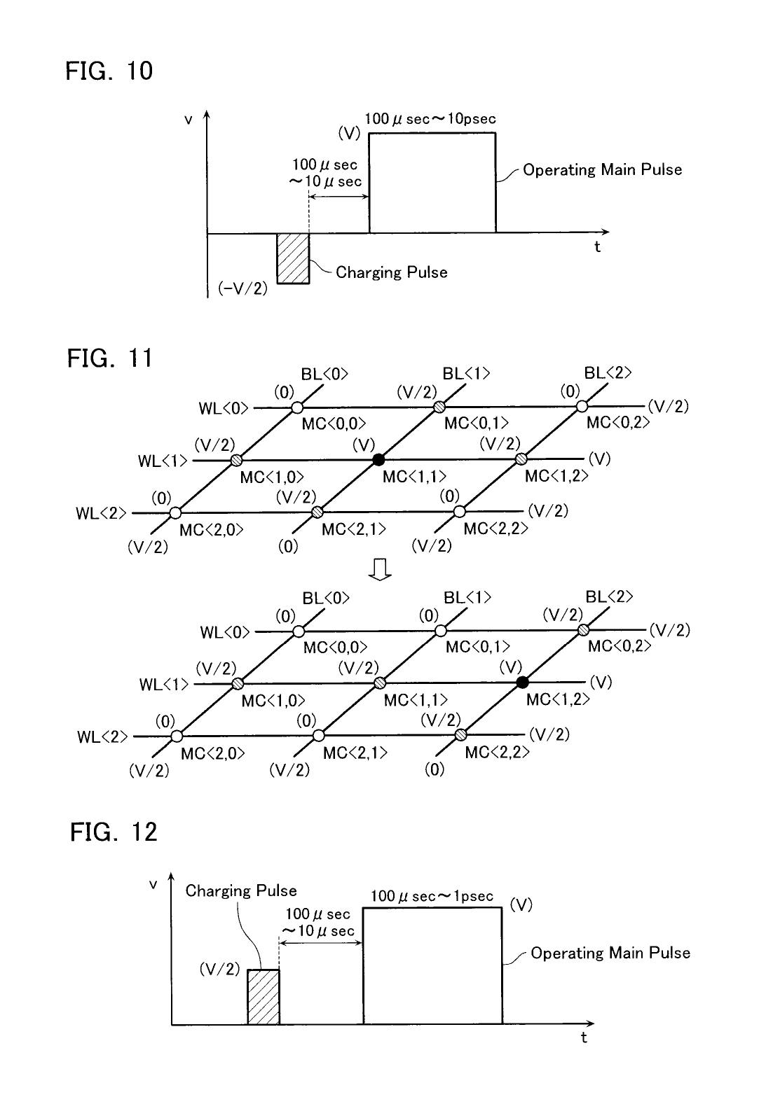

FIG. 10 is a diagram showing an example of electric pulses supplied to a memory cell at the time of write operation in the nonvolatile semiconductor memory device according to the embodiment. FIG. 10 shows voltage pulses supplied to a memory cell MC<1,2> when the memory cell array 1 is brought into the bias state shown in FIG. 9. In FIG. 10, a voltage pulse supplied to a memory cell MC<2,1> targeted to the next write operation, at the time of the former write operation to another memory cell MC<1,1>, is indicated as a ‘charging pulse’. In addition, a voltage pulse supplied to the memory cell MC<2,1> at the time of write operation to the memory cell MC<2,1> is indicated as an ‘operating main pulse’. The same indications go for the following diagrams.

As shown in FIG. 10, the memory cell MC<1,2> is provided with a potential difference −V/2 at the time of write operation to the memory cell MC<1,1>. Therefore, the rectifier element is charged by a carrier, that is, electric charge. Thereafter, the write operation is executed to the memory cell MC<1,2>. In a word, write operation to the memory cell MC<1,2> is executed to the memory cell MC<1,2> having the rectifier element charged by electric charge and accordingly it can be executed the write operation more surely.

Thus, in the embodiment, at the time of the former write operation to another memory cell MC, a rectifier element in a memory cell MC targeted to the next write operation is charged by electric charge. Therefore, according to the embodiment, it is not required to newly provide the processing time for charging the rectifier element by electric charge.

The following description is given to several examples of write operation in which the rectifier element of a memory cell MC targeted to the next write operation is charged by electric charge at the time of the former write operation to another memory cell MC.

FIG. 11 is a diagram showing another example of a bias state of a memory cell array at the time of write operation in the nonvolatile semiconductor memory device according to the embodiment.

This example also is an example using a variable resistance element that is subjected to the set/reset operation when the absolute value of a potential difference is equal to V or higher. It utilizes a middle voltage having an absolute value lower than V in charging the rectifier element by electric charge.

At the start, the write operation is executed to a selected memory cell, that is, a memory cell MC<1,1>. In this case, as shown in the upper part of FIG. 11, the data write unit is used to provide a selected word line WL<1> with a voltage V, non-selected word lines WL<0> and <2> with a voltage V/2, a selected bit line BL<1> with 0 V, and non-selected bit lines BL<0> and <2> with the voltage V/2. As a result, only a selected memory cell MC<1,1> is provided with a potential difference V, thereby executing set/reset operation to the selected memory cell MC<1,1>. In addition, half-selected memory cells MC<0,1>, <1,0>, <1,2> and <2,1> are provided with a potential difference V/2 (a first non-selection electric pulse). Non-selected memory cells MC<0,0>, <0,2>, <2,0> and <2,2> are provided with a potential difference 0 V (a second non-selection electric pulse).

Subsequently, write operation is executed to a selected memory cell, that is, a memory cell MC<1,2> (a second selected memory cell), which locates on the same word line WL<1> as the former selected memory cell MC<1,1> (a first selected memory cell). In this case, as shown in the lower part of FIG. 11, the data write unit is used to provide a selected word line WL<1> with a voltage V, non-selected word lines WL<0> and <2> with a voltage V/2, a selected bit line BL<2> with 0 V, and non-selected bit lines BL<0> and <1> with the voltage V/2. As a result, only a selected memory cell MC<1,2> is provided with a potential difference V (a selection electric pulse), thereby executing the set/reset operation.

FIG. 12 is a diagram showing an example of voltage pulses supplied to a memory cell at the time of write operation in the nonvolatile semiconductor memory device according to the embodiment. FIG. 12 shows voltage pulses supplied to a memory cell MC<1,2> when the memory cell array 1 is brought into the bias state shown in FIG. 11.

As shown in FIG. 12, the memory cell MC<1,2> is provided with a potential difference V/2 at the time of write operation to the memory cell MC<1,1>. Therefore, the rectifier element is charged by a carrier, that is, electric charge. Thereafter, the write operation is executed to the memory cell MC<1,2>. As shown in FIG. 12, the charging pulse is sufficient if it has such a level of electric energy that prevents the set/reset operation in the variable resistance element. In addition, it may have the same polarity as that of the operating main pulse for set/reset operation.

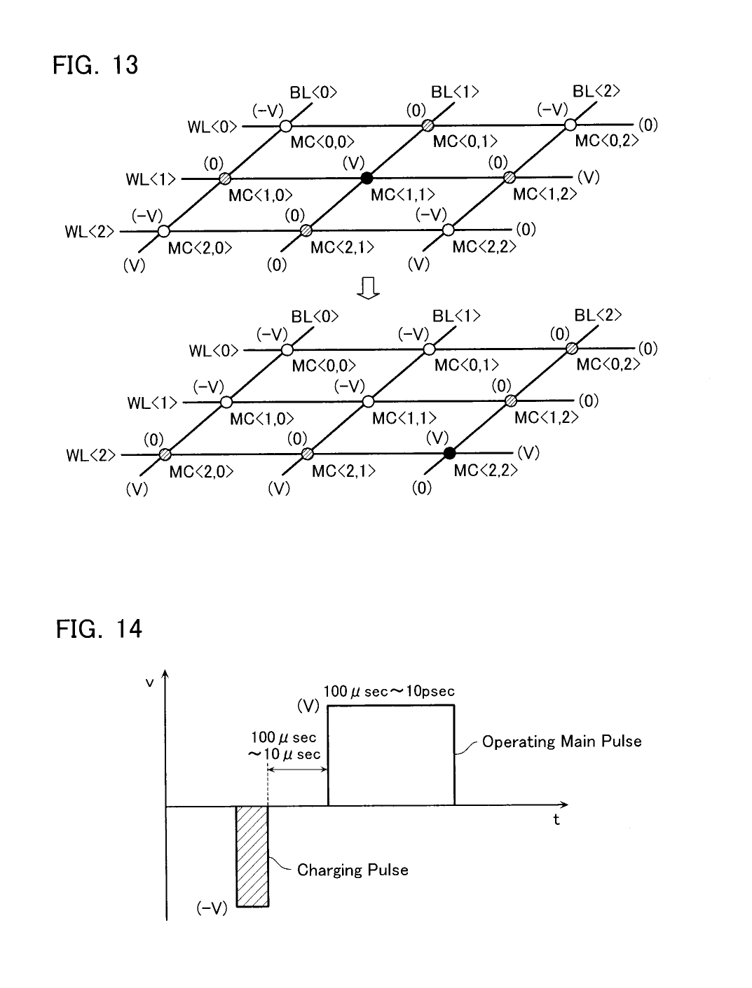

FIG. 13 is a diagram showing another example of a bias state of a memory cell array at the time of write operation in the nonvolatile semiconductor memory device according to the embodiment.

This example is an example using a variable resistance element that is subjected to the set/reset operation on a positive voltage. It utilizes a negative voltage in charging the rectifier element by electric charge.

At the start, the write operation is executed to a selected memory cell, that is, a memory cell MC<1,1>. In this case, as shown in the upper part of FIG. 13, the data write unit is used to provide a selected word line WL<1> with a voltage V, non-selected word lines WL<0> and <2> with 0 V, a selected bit line BL<1> with 0 V, and non-selected bit lines BL<0> and <2> with the voltage V. As a result, only a selected memory cell MC<1,1> is provided with a potential difference V, thereby executing set/reset operation to the selected memory cell MC<1,1>. In addition, non-selected memory cells MC<0,0>, <0,2>, <2,0> and <2,2> are provided with a potential difference −V (a first non-selection electric pulse). Half-selected memory cells MC<0,1>, <1,0>, <1,2> and <2,1> are provided with a potential difference 0 V (a second non-selection electric pulse).

Subsequently, the write operation is executed to a selected memory cell, that is, a memory cell MC<2,2> (a second selected memory cell) located between a word line WL<2> and a bit line BL<2> respectively adjacent to a word line WL<1> and a bit line BL<1> connected to the former selected memory cell MC<1,1> (a first selected memory cell), that is, a memory cell MC<2,2> arranged in a slanting direction from the memory cell MC<1,1>. In this case, as shown in the lower part of FIG. 13, the data write unit applies a voltage V to a selected word line WL<2>, 0 V to non-selected word lines WL<0> and <2>, 0 V to a selected bit line BL<2>, and the voltage V to non-selected bit lines BL<0> and <1>. As a result, only a selected memory cell MC<2,2> is provided with a potential difference V (a selection electric pulse), thereby executing set/reset operation to the memory cell MC<2,2>.

FIG. 14 is a diagram showing another example of electric pulses supplied to a memory cell at the time of write operation in the nonvolatile semiconductor memory device according to the embodiment. FIG. 14 shows electric pulses supplied to a memory cell MC<2,2> when the memory cell array 1 is put in the bias state shown in FIG. 13.

As shown in FIG. 14, the memory cell MC<2,2> is provided with a negative potential difference −V at the time of write operation to the memory cell MC<1,1>. Therefore, the rectifier element is charged by a carrier, that is, electric charge. Thereafter, the write operation is executed to the memory cell MC<2,2>. As shown in FIG. 12, the charging pulse is sufficient even if it has a large absolute value though it has a polarity that prevents set/reset operation in the variable resistance element.

In addition, in the case of FIGS. 9 and 11, memory cells connected to the same word line WL are sequentially selected to execute write operation. In contrast, in the case of FIG. 13, memory cells arranged in a slanting direction are sequentially selected to execute write operation. A carrier still remains in the rectifier element of the memory cell MC after the set/reset operation, thereby impairing the selectivity of the rectifier element. If memory cells MC are selected in a slanting direction as in the present example, however, it is possible to avoid failed the set/reset operation in the former selected memory cell caused under the influence of the remaining carrier. Further, in the following description, a method of write operation while sequentially selecting from among memory cells MC arranged in a slanting direction is referred to as a “slanting selection method”.

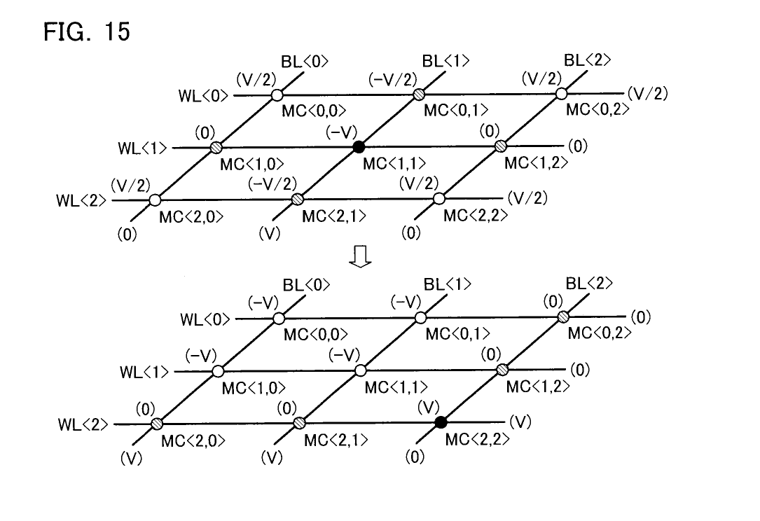

FIG. 15 shows another example of a bias state of a memory cell array at the time of write operation in the nonvolatile semiconductor memory device according to the embodiment.

This example also is an example using a variable resistance element that is subjected to set/reset operation when the absolute value of a potential difference is equal to V or higher. It utilizes a middle voltage having an absolute value lower than V in charging the rectifier element by electric charge.

At the start, write operation is executed to a selected memory cell, that is, a memory cell MC<1,1>. In this case, as shown in the upper part of FIG. 15, the data write unit is used to provide a selected word line WL<1> with 0 V, non-selected word lines WL<0> and <2> with a voltage V/2, a selected bit line BL<1> with a voltage V, and non-selected bit lines BL<0> and <2> with 0 V. As a result, only a selected memory cell MC<1,1> is provided with a potential difference −V having an absolute value of V or higher, thereby executing the set/reset operation. In addition, non-selected memory cells MC<0,0>, <0,2>, <2,0> and <2,2> are provided with a potential difference V/2 (a first non-selection electric pulse). Half-selected memory cells MC<0,1>, <1,0>, <1,2> and <2,1> are provided with a potential difference 0 V (a second non-selection electric pulse).

Subsequently, the write operation is executed to a selected memory cell, that is, a memory cell MC<2,2> (a second selected memory cell) arranged in a slanting direction from the former selected memory cell MC<1,1> (a first selected memory cell). In this case, as shown in the lower part of FIG. 15, the data write unit is used to provide a selected word line WL<2> with 0 V, non-selected word lines WL<0> and <1> with 0 V, a selected bit line BL<2> with 0 V, and non-selected bit lines BL<0> and <1> with a voltage V. As a result, only a selected memory cell MC<2,2> is provided with a potential difference V (a selection electric pulse), thereby executing the set/reset operation to the memory cell MC<2,2>.

In the case of the example of FIG. 15, the memory cell MC<2,2> is provided with a voltage V/2 at the time of write operation to the memory cell MC<1,1>. Therefore, the rectifier element is charged by a carrier, that is, electric charge. Thereafter, write operation is executed to the memory cell MC<2,2>. Also in the case of the present example, write operation in the slanting selection method is executed as in the example of FIG. 13. Therefore, it is possible to avoid failed the set/reset operation in the former selected memory cell caused under the influence of the remaining carrier.

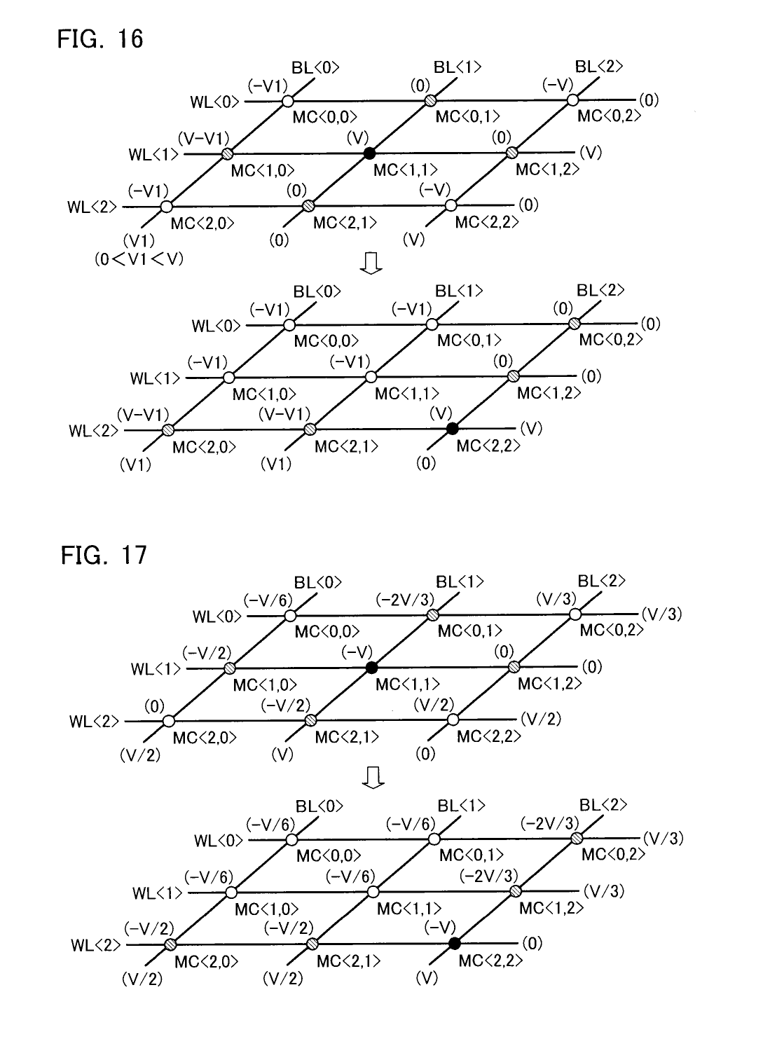

FIG. 16 shows another example of a bias state of a memory cell array at the time of write operation in the nonvolatile semiconductor memory device according to the embodiment.

This example is an example using a variable resistance element that is subjected to set/reset operation on a positive voltage. It utilizes a negative voltage in charging the rectifier element by electric charge.

At the start, write operation is executed to a selected memory cell, that is, a memory cell MC<1,1>. In this case, as shown in the upper part of FIG. 16, the data write unit applies a voltage V to a selected word line WL<1>, 0 V to non-selected word lines WL<0> and <2>, 0 V to a selected bit line BL<1>, a voltage V1 larger than 0 V and smaller than the voltage V to a non-selected bit line BL<0>, and the voltage V to a non-selected bit line <2>. As a result, only a selected memory cell MC<1,1> is provided with a potential difference V, thereby executing set/reset operation to the selected memory cell MC<1,1>. In addition, non-selected memory cells MC<0,0> and <2,2> are provided with a potential difference −V (a first non-selection electric pulse), and non-selected memory cells MC<2,0> and <2,2> and half-selected memory cells MC<0,1>, <1,0>, <1,2> and <2,1> are provided with a potential difference 0 V, −V1, or V−V1 (a second non-selection electric pulse).

Subsequently, the write operation is executed to a selected memory cell, that is, a memory cell MC<2,2> (a second selected memory cell) arranged in a slanting direction from the former selected memory cell MC<1,1> (a first selected memory cell). In this case, as shown in the lower part of FIG. 16, the data write unit applies a voltage V to a selected word line WL<2>, 0 V to non-selected word lines WL<0> and <2>, 0 V to a selected bit line BL<2>, and a voltage V1 to non-selected bit lines BL<0> and <1>. As a result, only a selected memory cell MC<2,2> is provided with a potential difference V (a selection electric pulse), thereby executing set/reset operation to the selected memory cell MC<2,2>.

This example uses three voltages as voltages applied to word lines WL, including 0 V, the voltage V, and additionally the voltage V1 (0<V1<V). As a result, it is possible to create two types of large and small negative voltages applied to non-selected memory cells MC. This is utilized to place a large negative potential difference across a memory cell MC<2,2> to be selected next. Conversely, write operation is executed to the next selected memory cell MC, that is, a memory cell MC<2,2> provided with a large negative potential difference. Thus, the next selected memory cell MC<2,2> originally requiring impact ionization of the rectifier element can be provided with a charging pulse having a negative potential difference −V for charging the rectifier element by electric charge. In addition, memory cells MC<0,0> and so forth not requiring impact ionization of the rectifier element can be provided only with a negative potential difference −V1 or the like having smaller electric energy. Therefore, it is possible to reduce excessive charging of the rectifier element by electric charge and further suppress the occurrence of failed the set/reset operation.

FIG. 17 shows another example of a bias state of a memory cell array at the time of write operation in the nonvolatile semiconductor memory device according to the embodiment.

This example also is an example using a variable resistance element that is subjected to the set/reset operation when the absolute value of a potential difference is equal to V or higher. It utilizes a positive middle voltage lower than the voltage V in charging the rectifier element by electric charge.

At the start, write operation is executed to a selected memory cell, that is, a memory cell MC<1,1>. In this case, as shown in the upper part of FIG. 17, the data write unit applies 0 V to a selected word line WL<1>, a voltage V/3 to a non-selected word line WL<0>, a voltage V/2 to a non-selected word line WL<2>, a voltage V to a selected bit line BL<1>, a voltage V/2 to a non-selected bit line BL<0>, and 0 V to a non-selected bit line <2>. As a result, only a selected memory cell MC<1,1> is provided with a potential difference −V having a potential-difference absolute value of V or higher, thereby executing set/reset operation to the selected memory cell MC<1,1>. In addition, non-selected memory cells include a non-selected memory cell MC<2,2> provided with the largest positive potential difference V/2 (a first non-selection electric pulse), and a non-selected memory cell MC<0,2> provided with a potential difference V/3 (a second non-selection electric pulse).

Subsequently, the write operation is executed to a selected memory cell, that is, a memory cell MC<2,2> (a second selected memory cell) arranged in a slanting direction from the former selected memory cell MC<1,1> (a first selected memory cell). In this case, as shown in the lower part of FIG. 17, the data write unit applies 0 V to a selected word line WL<2>, a voltage V/3 to non-selected word lines WL<0> and <2>, a voltage V to a selected bit line BL<2>, and a voltage V/2 to non-selected bit lines BL<0> and <1>. As a result, only a selected memory cell MC<2,2> is provided with a potential difference −V (a selection electric pulse) having an absolute value of V or higher, thereby executing set/reset operation to the selected memory cell MC<2,2>.

This example uses three voltages as voltages applied to word lines WL, similar to FIG. 16, including 0 V, the voltage V/2, and additionally the voltage V/3. In addition, it uses three voltages as voltages applied to bit lines BL, including 0 V, the voltage V, and additionally the voltage V/2. As a result, it is possible to create two types of large and small positive voltages applied to non-selected memory cells MC. This is utilized to provide with a large positive potential difference across a memory cell MC<2,2> to be selected next. Conversely, write operation is executed to the next selected memory cell MC, that is, a memory cell MC<2,2> provided with a large positive potential difference. Thus, only the next selected memory cell MC<2,2> originally requiring impact ionization of the rectifier element can be provided with a sufficient positive potential difference V/2 for charging the rectifier element by electric charge. In addition, other memory cells MC<0,0> and so forth can be provided only with a negative voltage or a smaller positive potential difference. Therefore, it is possible to further reduce excessive charging of the rectifier element by electric charge compared to the example of FIG. 16.

### [Address Assignments to Memory Cells]

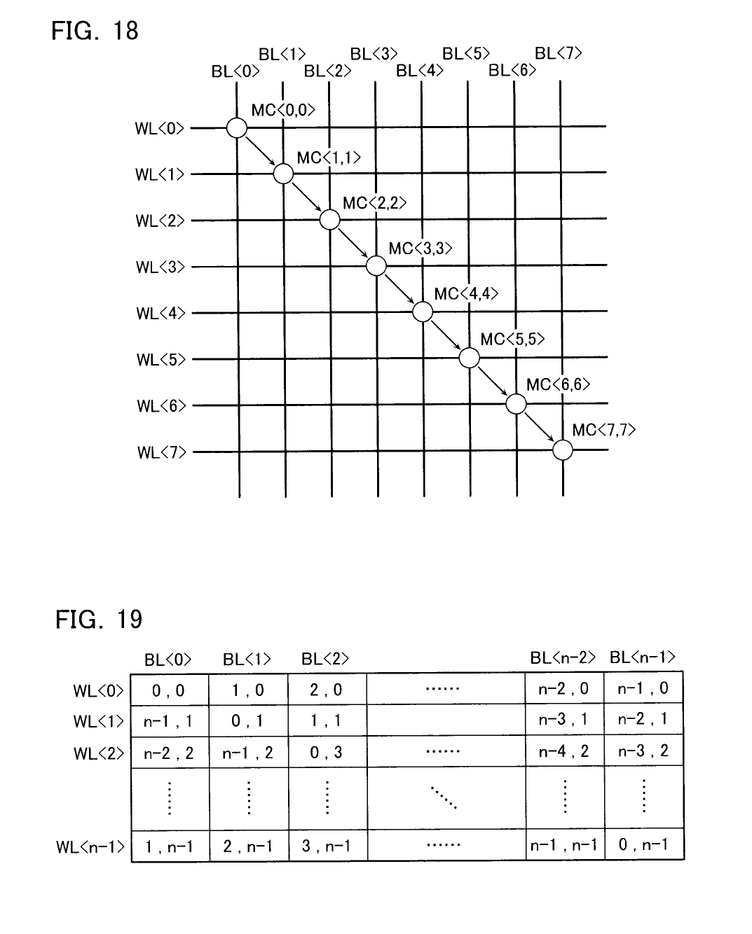

FIG. 18 is a diagram illustrative of an example of the selecting order of memory cells at the time of write operation in the nonvolatile semiconductor memory device according to the embodiment.

As above, several examples of write operation using impact ionization phenomena have been shown. Among those, in the case of the examples of FIGS. 13 and 15-17, the slanting selection method of sequentially selecting from among memory cells MC arranged in the slanting direction as shown in FIG. 18 is used to execute write operation. Usually, however, address assignments to memory cells MC are executed along the word line WL or the bit line BL. In the case of such address assignments, execution of write operation in the slanting selection method requires complicated address decoding.

The following description is given to examples of address assignments to memory cells MC suitable for write operation in the slanting selection method.

FIG. 19 is a diagram illustrative of an example of address assignments to memory cells in the nonvolatile semiconductor memory device according to the embodiment. FIG. 19 shows address assignments to memory cells MC corresponding to the write operation in the slanting selection method shown in FIG. 18. In addition, FIG. 19 premises a cell array 1 including n×n memory cells MC (n is an integer of 2 or more).

In the case shown in FIG. 19, physical addresses <0,0>, <1,1>, . . . , <n−2,n−2>, <n−1,n−1> of memory cells MC are assigned with logical addresses <0,0><0,1>, . . . , <0,n−2>, <0,n−1>. In addition, physical addresses <0,1>, <1,2>, . . . , <n−2,n−1>, <n−1,0> of memory cells MC are assigned with logical addresses <1,0>, <1,1>, . . . , <1,n−2>, <1,n−1>. Thereafter, address assignments are similarly executed, and a physical address <n−1,n−2> of a memory cell MC is assigned with a logical address <n−1,n−1>.

It possible to realize write operation in the slanting selection method just by selecting from among memory cells MC in order of address such as the address assignments to memory cells MC as shown in FIG. 19.

The slanting selection method described above includes selecting a word line WL<i> (i=0 to n−1) and a bit line BL<j> (j=0 to n−1), and then selecting an adjacent word line WL<i+1> and an adjacent bit line BL<j+l>. It is possible to avoid set/reset operation fail due to the remaining carrier by not successively selecting from among memory cells MC connected to the same word line WL or the same bit line BL.

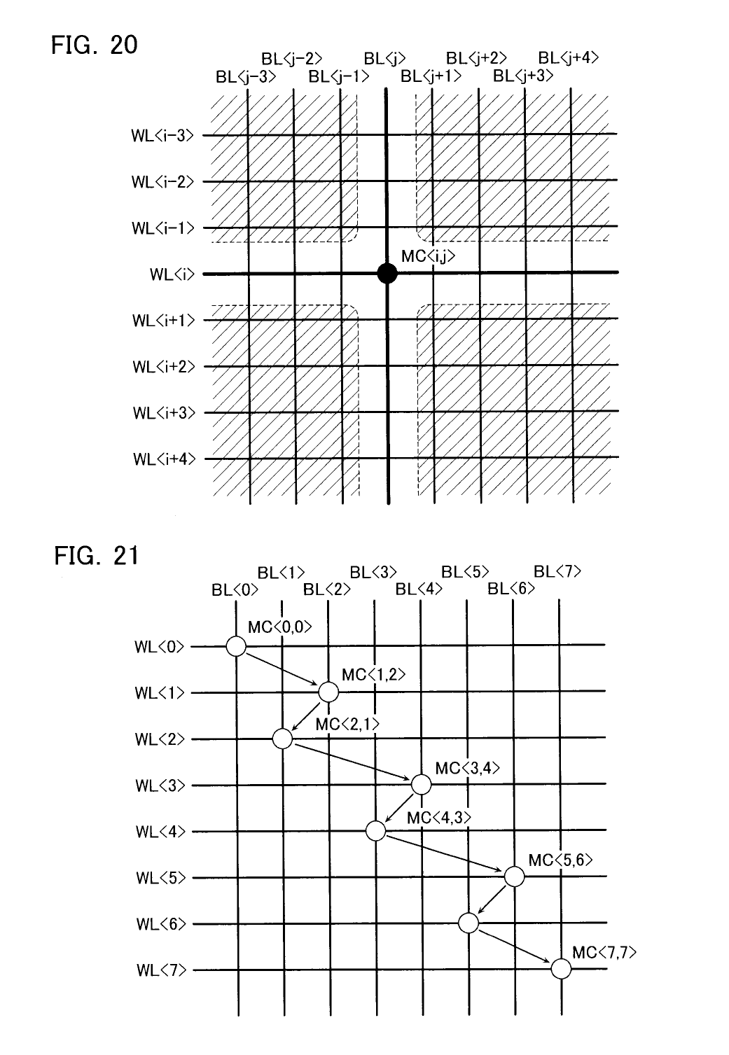

FIG. 20 is a diagram illustrative of the selecting order at the time of write operation in the nonvolatile semiconductor memory device according to the embodiment.

In a word, the effect of the slanting selection method can be exerted by selecting a memory cell MC<i,j> between a word line WL<i> and a bit line BL<j>, and then selecting a memory cell MC other than the memory cell MC connected to the word line WL<i> or the bit line BL<j>, that is, a memory cell MC just within ranges hatched in FIG. 20.

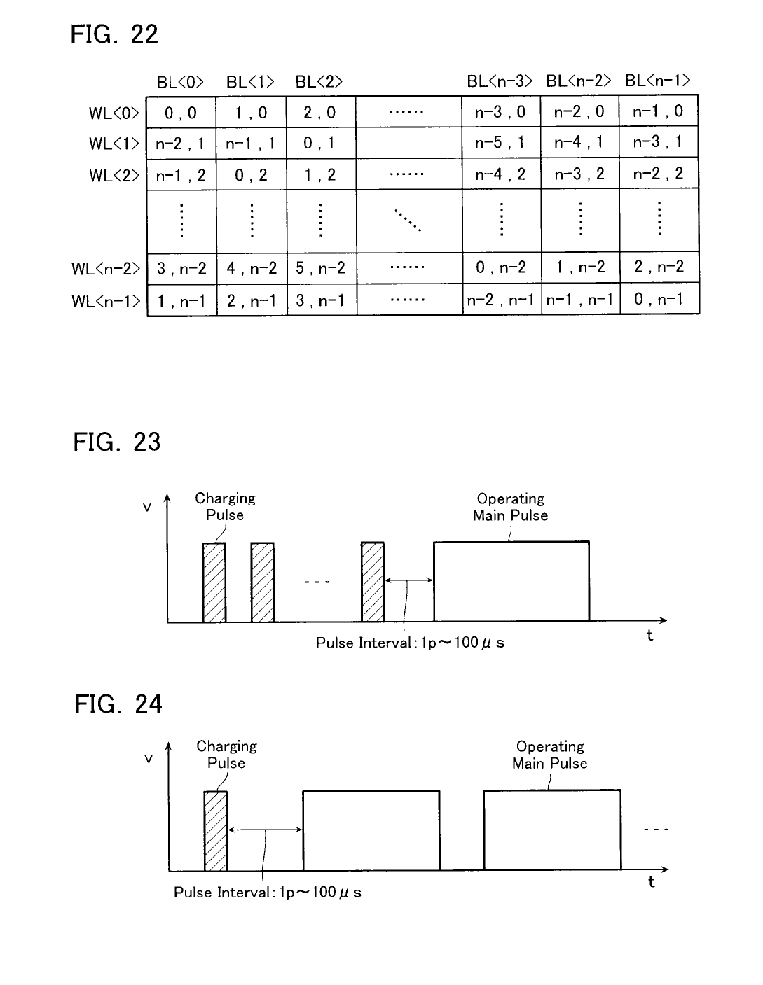

FIG. 21 is a diagram illustrative of an example of the selecting order of memory cells at the time of write operation in the nonvolatile semiconductor memory device according to the embodiment. FIG. 22 is a diagram illustrative of an example of address assignments to memory cells in the nonvolatile semiconductor memory device according to the embodiment. It shows address assignments to memory cells MC corresponding to write operation in the slanting selection method shown in FIG. 21.

Instead of selecting from among memory cells MC connected to the same word line WL or the same bit line BL successively as in order of physical address <0,0>, <1,2>, <2,1>, <3,4>, <4,3>, <5,6>, <6,5>, <7,7>, . . . of memory cells MC as shown in FIG. 21, it is preferable to select from among memory cells MC based on any numerical sequence or rule. The example shown in FIG. 21 is an example of selecting from among memory cells MC while physical addresses of bit lines BL alternate as in +2, −1, +3, −1, +2, −1, . . . every time the physical address of the word line WL increments by one.

At the end, several variations of the charging pulse and the operating main pulse are listed and described briefly.

The charging pulse and the operating main pulse are described as rectangular pluses in the above examples though they are not limited thereto.

FIGS. 23-28 are diagrams showing examples of electric pulses supplied to a memory cell at the time of write operation in the nonvolatile semiconductor memory device according to the embodiment.

In the case shown in FIG. 23, charging pulses are supplied before an operating main pulse. In the case shown in FIG. 24, charging pulses are supplied times after an operating main pulse is supplied once. As in these cases, it is preferable in the embodiment to accumulate electric charge in the rectifier element to make an on-current easily flowing state before the operating main pulse. Accordingly, the number of times of the charging pulse and the operating main pulse has no limitation. Therefore, it is possible to set an appropriate number of times of the charging pulse and the operating main pulse in consideration of the processing speed for set/reset operation and the influence of heat generated.

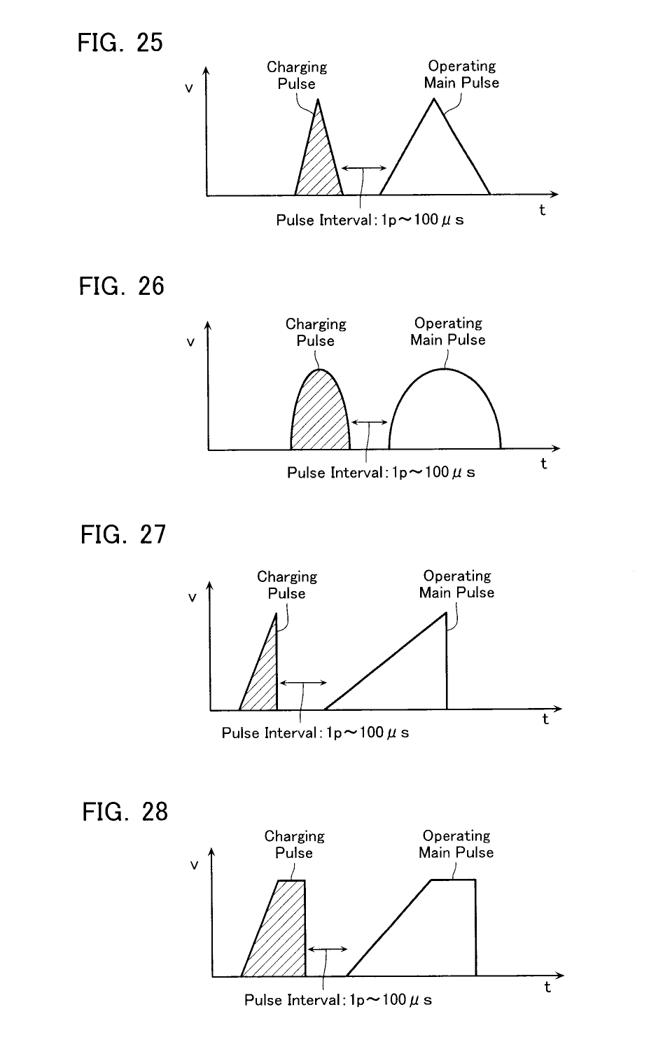

In addition, the shapes of the charging pulse and the operating main pulse may include triangles shown in FIG. 25, semi-ellipses shown in FIG. 26, serrations shown in FIG. 27, and trapezoids shown in FIG. 28.

In practice, even when a rectangular electric pulse as shown in FIG. 10 and so forth is supplied, the influence of parasitic capacity caused on a word line WL or a bit line BL, for example, may dull the waveform. Containing such the unintended case, the shapes of the charging pulse and the operating main pulse can be set arbitrarily. Further, the shapes of the charging pulse and the operating main pulse may differ from each other. In addition, the charging pulse is sufficient if it has electric energy within a range that prevents set/reset operation. Therefore, it can be adjusted in accordance with the height, width or polarity of the electric pulse, or the combination thereof.

### CONCLUSION

As above, in accordance with the embodiment, the rectifier element is charged by electric charge for impact ionization before the set/reset operation.

Therefore, it is possible to gain the on/off ratio of the rectifier element and realize surer set/reset operation. In addition, the charging pulse for impact ionization is supplied at the time of the former write operation to another memory cell. Therefore, it is not required to newly provide the processing time for charging by electric charge. In addition, it possible to avoid failed set/reset operation due to the remaining carrier by the slanting selection method at the write operation.

### OTHERS

While the embodiments of the present invention have been described, these embodiments are presented by way of example and are not intended to limit the scope of the invention. These novel embodiments can be implemented in a variety of other forms, and various omissions, substitutions and changes can be made without departing from the spirit of the invention. These embodiments and variations thereof would fall within the scope and spirit of the invention and also fall within the invention recited in claims and equivalents thereof.

1. A nonvolatile semiconductor memory device, comprising:
a memory cell array including first lines, second lines intersecting said first lines, and memory cells arranged at the intersections of said first lines and said second lines; and
a data write unit configured to execute a write operation to said memory cells,
said memory cells including a memory element and a selection element,
said memory cells including a first selected memory cell being a target of said write operation, a second selected memory being a next target of said write operation, and non-selected memory cells, and
said data write unit, during said write operation to said first selected memory cell, providing said second selected memory cell with a first non-selection electric pulse having electric energy within a range causing no change in the physical state of said memory element, and providing said non-selected memory cells with a second non-selection electric pulse having smaller electric energy than said first non-selection electric pulse.

2. The nonvolatile semiconductor memory device according to claim 1, wherein
said second selected memory cell is connected to one of said first lines different from said first connected to said first selected memory cell, and one of said second lines adjacent to said second line connected to said first selected memory cell.

3. The nonvolatile semiconductor memory device according to claim 1, wherein
said second selected memory cell is connected to one of said first lines adjacent to said first line connected to said first selected memory cell, and one of said second lines different from said second line connected to said first selected memory cell.

4. The nonvolatile semiconductor memory device according to claim 1, wherein
said second selected memory cell is connected to one of said first line connected to said first selected memory cell and said second line connected to said first selected memory cell.

5. The nonvolatile semiconductor memory device according to claim 1, wherein
said selection element is formed of semiconductors.

6. The nonvolatile semiconductor memory device according to claim 1, wherein
said selection element is a nonlinear element.

7. The nonvolatile semiconductor memory device according to claim 1, wherein
said selection element is a rectifier element having a structure composed of a p-type semiconductor/an intrinsic semiconductor/an n-type semiconductor, a p-type semiconductor/an n-type semiconductor/a p-type semiconductor, or an n-type semiconductor/a p-type semiconductor/an n-type semiconductor.

8. The nonvolatile semiconductor memory device according to claim 1, wherein
said data write unit applies three or more different potentials to said first lines during said write operation.

9. The nonvolatile semiconductor memory device according to claim 1, wherein
said data write unit applies three or more different potentials to said second lines during said write operation.

10. A nonvolatile semiconductor memory device, comprising:
a memory cell array including first lines, second lines intersecting said first lines, and memory cells arranged at the intersections of said first lines and said second lines; and
a data write unit operative to execute a write operation to said memory cells,
said memory cells including a memory element and a selection element,
said memory cells including a first selected memory cell being a target of said write operation, a second selected memory cell being a next target of said write operation, and non-selected memory cells,
said data write unit, during said write operation to said first selected memory cell, providing said second selected memory cell with a first non-selection potential difference, and providing said non-selected memory cells with a second non-selection potential difference smaller than said first non-selection potential difference, and
said first non-selection potential difference being smaller than a selection potential difference provided to said second selected memory cell during said write operation to said second selected memory cell.

11. The nonvolatile semiconductor memory device according to claim 10, wherein
said first non-selection potential difference has the same polarity as that of said selection potential difference.

12. The nonvolatile semiconductor memory device according to claim 10, wherein
said second selected memory cell is connected to one of said first lines different from said first lines line connected to said first selected memory cell, and one of said second lines different from said second line connected to said first selected memory cell.

13. The nonvolatile semiconductor memory device according to claim 10, wherein
said second selected memory cell is connected to one of said first lines adjacent to said first line connected to said first selected memory cell, and one of said second lines adjacent to said second line connected to said first selected memory cell.

14. The nonvolatile semiconductor memory device according to claim 10, wherein
said second selected memory cell is connected to one of said first line connected to said first selected memory cell and said second line connected to said first selected memory cell.

15. The nonvolatile semiconductor memory device according to claim 10, wherein
said selection element is a rectifier element having a structure composed of a p-type semiconductor/an intrinsic semiconductor/an n-type semiconductor, a p-type semiconductor/an n-type semiconductor/a p-type semiconductor, or an n-type semiconductor/a p-type semiconductor/an n-type semiconductor.

16. A nonvolatile semiconductor memory device, comprising:
a memory cell array including first lines, second lines intersecting said first lines, and memory cells arranged at the intersections of said first lines and said second lines; and
a data write unit operative to execute a write operation to said memory cells,
said memory cells including a memory element and a selection element,
said memory cells including a first selected memory cell being a target of said write operation, a second selected memory cell being a next target of said write operation, and non-selected memory cells,
said data write unit, during said write operation to said first selected memory cell, providing said second selected memory cell with a first non-selection potential difference, and providing said non-selected memory cells with a second non-selection potential difference smaller than said first non-selection potential difference, and
said first non-selection potential difference having a different polarity from that of a selection potential difference supplied to said second selected memory cell at during said write operation to said second selected memory cell.

17. The nonvolatile semiconductor memory device according to claim 16, wherein
said second selected memory cell is connected to one of said first lines different from said first line connected to said first selected memory cell, and one of said second lines different from said second line connected to said first selected memory cell.

18. The nonvolatile semiconductor memory device according to claim 16, wherein
said second selected memory cell is connected to one of said first lines adjacent to said first and second lines line connected to said first selected memory cell, and one of said second lines adjacent to said second line connected to said first selected memory cell.

19. The nonvolatile semiconductor memory device according to claim 16, wherein
said second selected memory cell is connected to one of said first and line connected to said first selected memory cell and said second line connected to said first selected memory cell.

20. The nonvolatile semiconductor memory device according to claim 16, wherein
said selection element is a rectifier element having a structure composed of a p-type semiconductor/an intrinsic semiconductor/an n-type semiconductor, a p-type semiconductor/an n-type semiconductor/a p-type semiconductor, or an n-type semiconductor/a p-type semiconductor/an n-type semiconductor.
